(19) United States
(12) Patent Application Publication
(10) Pub. No.: US 2009/0285035 A1
(43) Pub. Date: Nov. 19, 2009

(54) Pipelined wordline memory architecture

(76) Inventors: Tyler Lee Brandon, Edmonton (CA); Duncan George Elliott, Edmonton (CA)

Correspondence Address: Duncan Elliott, 9107 - 116 Street, Edmonton, AB, T6G 2V4, omitted

(21) Appl. No.: 12/468,046

(22) Filed: May 18, 2009

Related U.S. Application Data
(60) Provisional application No. 61/071,768, filed on May 16, 2008.

(51) Int. Cl. G11C 7/10; G11C 8/00; G11C 7/00

(52) U.S. Cl. 365/189.05; 365/230.01; 365/194

(57) ABSTRACT

A method is provided for reducing semiconductor memory wordline propagation delays of long wordlines by inserting pipeline registers in the wordlines between groups of memory cells.

### U.S. PATENTS CITED

Barth, et al., Apparatus and method for pipelined memory operations, 2008, U.S. Pat. No. 7,353,357

Barth, et al., Apparatus and method for pipelined memory operations, 2008, U.S. Pat. No. 7,330,951

Rao, Pipelined semiconductor memories and systems, 2007, U.S. Pat. No. 7,254,690

Wood, et al., SRAM circuitry, 2007, U.S. Pat. No. 7,193,887

Tanoi, Semiconductor memory with improved word line structure, 1998, U.S. Pat. No. 5,708,621

Min, et al., Arrangement of word line driver stage for semiconductor memory device, 1994, U.S. Pat. No. 5,319,605.

### STATEMENT REGARDING FEDERALLY SPONSORED RESEARCH OR DEVELOPMENT

Not applicable

### REFERENCE TO SEQUENCE LISTING, A TABLE, OR A COMPUTER PROGRAM LISTING COMPACT DISK APPENDIX

Not applicable

### FIELD OF THE INVENTION

This invention relates to wordline architecture in semiconductor integrated circuit memory.

### BACKGROUND OF THE INVENTION

Multiple memory technologies have arrays of memory cells where each cell is enabled by a wordline and data is read from or written to the memory cell via a bitline or pair of complementary bitlines. In the case of a 2-dimensional array, a single wordline is driven to a voltage that enables the memory cells connected to that wordline.

The propagation delay of the wordline signal along the wordline wire depends in part on the resistance and capacitance of the wordline, each of which increase with the length of the wordline and the number of cells a wordline connects to. The wordline propagation delay can be reduced by building smaller arrays of memory cells with shorter wordlines at the expense of a smaller memory or more wordline decoders. These multiple memory cell arrays in the same integrated circuit are typically referred to as memory subarrays in the literature. The wordline resistance can be reduced by adding metal wires in parallel to polycrystalline silicon wires.

In U.S. Pat. No. 5,319,605, Min teaches the use of hierarchical wordlines with a global wordline connected to multiple drivers that drive local wordlines, thereby reducing the capacitive load on the global wordline.

Different aspects of memories have been pipelined before, including wordline drivers. In U.S. Pat. Nos. 7,353,357 and 7,330,951, Barth teaches the pipelining of memory requests outside of the memory cell array.

### SUMMARY OF THE INVENTION

The disclosed pipelined wordline memory architecture places synchronous sequencing elements between segments of non-hierarchical or hierarchical wordlines. A plurality of sequencing elements are referred to here as a pipeline register. This architecture permits memories to have short high-speed divided wordlines without the semiconductor area or delays of wordline decoders or local-wordline decoders. In the prior art, fast memories could be small capacity or have multiple subarrays, each subarray with its own wordline decoders or local wordline decoders in the case of divided wordline architectures. A fast and low-semiconductor-area alternative to this prior art is to use a conventional wordline decoder for the first memory subarray and use the far end of each wordline of any subarray as input to a pipeline register that drives the wordlines of the next one or more subarrays. All such pipeline registers could be coupled to a common clock.

Some applications can tolerate the delayed addressing present in subsequent memory cell arrays employing the pipelined wordline memory architecture. This delay is desirable in some architectures of pipelined low density parity check convolutional code decoders. A wide-word FIFO implemented as a circular buffer could span multiple pipelined wordline memory architecture memory banks, provided that reads and writes are to the same address (where a read is followed by a write to the same memory cells in the same memory cycle) or that reads and writes alternate and that the pipelined wordline architecture contain multiple pipeline registers as described in the detailed summary.

A pipelined wordline memory architecture memory could be used as local memory for multiple SIMD (single instruction stream, multiple data stream) processing elements, provided that the shared instruction stream is also pipelined in a similar manner to the wordlines.

A pipeline register could be a D-Flip Flop, a pulsed latch, dynamic latch, a dynamic latch followed by a static latch or other such variants that hold a value until a control signal (i.e. a clock signal) triggers them to update their held value.

### BRIEF DESCRIPTION OF THE DRAWINGS

In the accompanying drawings:

FIG. 1 is a diagram of the pipelined wordline architecture. Pipeline registers couple the wordline signals used in one memory cell array or subarray, delaying the signals to the next clock cycle before sending these wordline signals on to the next memory cell array or subarray.

FIG. 2 shows an alternative embodiment where multiple memory cell arrays are present before a pipeline register couples the wordlines.

FIG. 3 shows an alternative embodiment of the pipelined wordline architecture, where two sets of pipeline registers delay the wordline signals to the second clock cycle before sending these wordline signals on to the next memory array or subarray. This has application for building a FIFO where the read and write address are different and one operation takes place on even cycles while the other operation takes place on odd cycles. More than two such operations and sets of addresses can be interleaved with the corresponding number of intervening pipeline registers producing the necessary clock cycle delays.

### DETAILED DESCRIPTION OF THE INVENTION

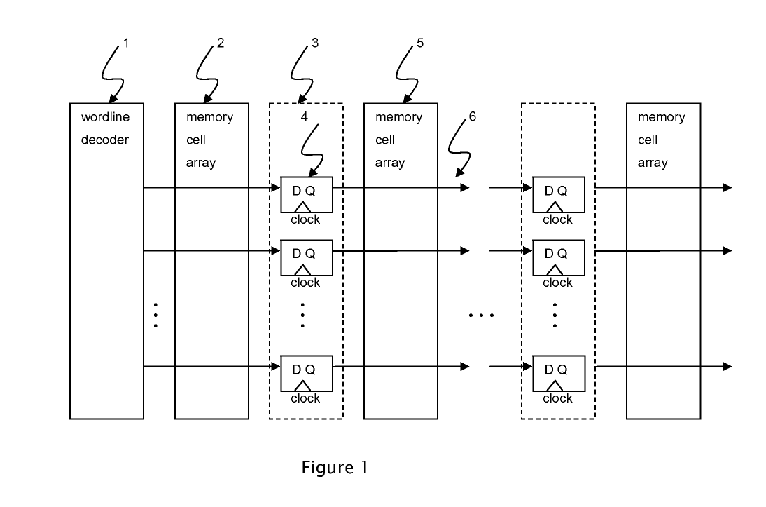

In FIG. 1, the synchronous sequencing element depicted is a D-flipflop (indicated in the figure by number 4). Collectively, these synchronous sequencing element depicted in the same column form a pipeline register (3). Wordline signals are first generated by wordline decoders (1). Some implementations of wordline decoders are themselves pipelined. These wordline signals pass through a memory cell array. A wordline, after passing through a memory cell array (2) where it is coupled to memory cells, is delayed to the next clock cycle by a pipeline register (3) before this delayed wordline signal (6) is coupled to another memory cell array (5). Although the pipelining of wordlines delays signals by a cycle, potentially shorter wordlines could have a shorter memory cycle.

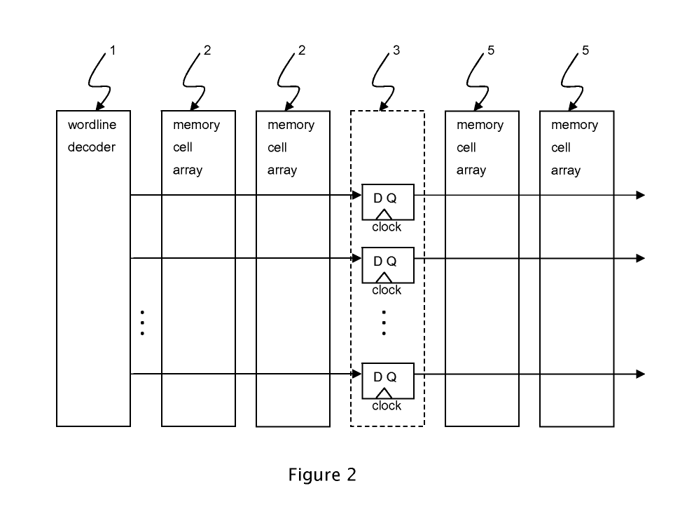

A wordline signal may traverse one or more memory arrays or memory subarrays before encountering a pipeline register. In FIG. 2, multiple memory cell arrays (2) use the same wordlines or global wordlines before delaying the wordline signals to the next clock cycle with a pipeline register.

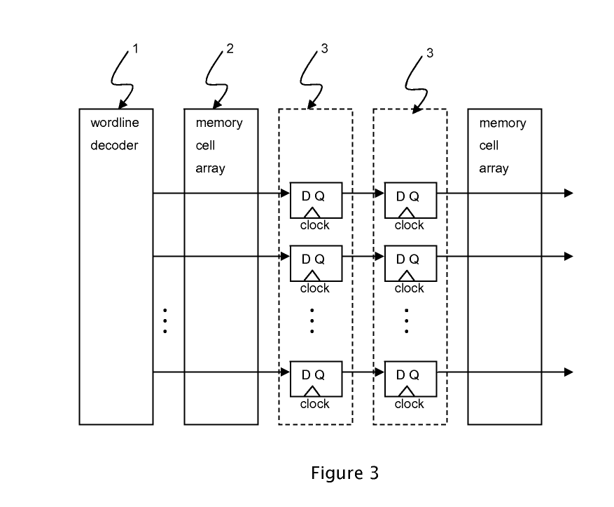

In FIG. 3, multiple pipeline registers (3) are placed between memory cell arrays (2), to create the desired pipeline delay in the wordline signals propagating between memory arrays. Combinations of multiple adjacent memory cell arrays with multiple adjacent pipeline register are an alternative embodiment.

What is claimed is:

1. A memory where wordlines coupled to memory cells are also coupled to pipeline registers that are coupled to memory cells.

2. The memory in claim 1 where the wordlines coupled by pipeline registers are global wordlines.

3. The memory in claim 1 where the wordlines coupled by pipeline registers are local wordlines.

4. The memory in claim 1 where the pipeline registers delay the wordline signals one clock cycle.

5. The memory in claim 1 where the pipeline registers delay the wordline signals two or more clock cycles.

6. The memory in claim 1 where the pipeline registers consist of flip flops.

7. The memory in claim 1 where the pipeline registers consist of latches.

8. The memory in claim 1 where the pipeline registers consist of pulse latches.

9. The memory in claim 1 where the pipeline registers consist of dynamic latches.

10. The memory in claim 1 where the pipeline registers consist of static latches.

11. The memory in claim 1 where the pipeline registers consist of dynamic and static latches.

12. A method of operating a semiconductor memory where the wordline address of the selected cells is the same as the wordline address of other selected cells in one of the preceding cycles.

13. The method of operating a semiconductor memory in claim 12 where the wordline address of the selected cells in a second memory cell array is the same as the wordline address of selected cells in a first adjacent memory cell array in the preceding cycle.

14. The method of operating a semiconductor memory in claim 12 where the wordline address of the selected cells in a second memory cell array is the same as the wordline address of selected cells in a first adjacent memory cell array in a previous cycle.
